(19) United States
(12) Patent Application Publication
(10) Pub. No.: US 2025/0096109 A1
(43) Pub. Date: Mar. 20, 2025

(54) WAFER-LEVEL POWER MODULE AND MANUFACTURING METHOD THEREFOR

(71) Applicant: SHANGHAI METAPWR ELECTRONICS CO., LTD, Shanghai (CN)

(72) Inventor: Jianhong ZENG, Shanghai (CN)

(73) Assignee: SHANGHAI METAPWR ELECTRONICS CO., LTD, Shanghai (CN)

(21) Appl. No.: 18/963,821

(22) Filed: Nov. 29, 2024

Related U.S. Application Data
(63) Continuation of application No. PCT/CN2023/097285, filed on May 30, 2023.

(30) Foreign Application Priority Data
May 31, 2022 (CN) 202210612515.1

(51) Int. Cl. H01L 23/498; H01L 21/304; H01L 21/768; H01L 21/78; H10D 1/20; H10D 1/68

(52) U.S. Cl. CPC H01L 23/49844; H01L 21/304; H01L 21/76873; H01L 21/78; H01L 23/49827; H10D 1/20; H10D 1/68

(57) ABSTRACT

The application discloses a wafer-level power module and a manufacturing method thereof. The wafer-level power module comprises a wafer and a passive element, the wafer comprises a wafer functional area, and the wafer functional area is located on the first surface of the wafer; the passive element comprises at least one power pin, the passive element is stacked on the second surface of the wafer, the wafer functional area is electrically connected to the second surface of the wafer from the first surface of the wafer through a conductive path and is electrically connected with the power pin of the passive element, and the conductive path is attached to the wafer.

### CROSS-REFERENCE TO RELATED APPLICATION

This application is a continuation of international application of PCT patent application PCT/CN2023/097285, filed on May 30, 2023, which claims the priority benefit of China application no. 202210612515.1 filed on May 31, 2022. The entirety of each of the above-mentioned patent applications is hereby incorporated by reference herein and made a part of this specification.

### BACKGROUND

With the continuous development of economic society, people have higher dependence on intelligent equipment, like Bluetooth earphones, smart phones, smart watches and the like. For example, the Bluetooth earphone can be smaller and exquisite, and the appearance is more exquisite; for example, the intelligent watch is more powerful in function; for example, the intelligent mobile phone is expected to be thinner and lighter. A major factor limiting the development of the power supply is that the size of the used power supply is too large and too thick, so that higher requirements are provided for the design of the power supply.

As shown in FIG. 1A, a cross-sectional view of the circuit is shown in FIG. 1B and FIG. 1C. It can be seen from the figure that the wafer is embedded in a substrate, and then an inductor is placed above the substrate to form a power module. As shown in FIG. 1B, in order to meet more efficient production, the substrate is usually made into a large connecting piece, then an inductor is attached to the large connecting piece, and finally the substrate with the large connecting piece is de-paneled to form an independent unit, so that the size of the inductor is smaller than the size of the substrate to reserve the cutting distance, for example, 0.2 mm is reserved on the single side, and the performance is reduced due to the waste of the extra size. Therefore, in order to solve the problem, the substrate can be pre-cut from the front side, that is, the cutting depth is about half of the thickness of the substrate, at the moment, the substrate is still a large connecting piece structure, then the substrate is attached with an inductor, and finally the large connecting piece structure is divided into independent units from the bottom face of the substrate. As shown in FIG. 1C, the inductor utilization rate of the structure is very high, and compared with FIG. 1B, the efficiency can be obviously improved.

However, for the power module shown in FIG. 1C, the thickness of the industry can be basically controlled below 1 mm, wherein the packaging thickness of the substrate is at least 0.15 mm, the thickness of the wafer in the substrate is at least 0.15 mm, that is, the total thickness H2 of the whole substrate is at least 0.3 mm, which accounts for at least 30% of the total thickness of the whole module. According to market requirements, the power supply module is developed in a thinner direction, for example, 0.8 mm or even 0.5 mm, and the packaging structure shown in FIG. 1C is not suitable for future occasions.

### SUMMARY

In view of the above, one of the objectives of the present application is to provide a wafer-level power module comprising:
a wafer, the wafer comprising a wafer functional area, and the wafer functional area being located on a first surface of the wafer;

The passive element comprises at least one power pin, the passive element is stacked on the second surface of the wafer, and the wafer functional area is electrically connected to the second surface of the wafer from the first surface of the wafer through a conductive path and is electrically connected with the power pin of the passive element;

The conductive path is attached to the wafer.

Preferably, wherein the conductive path comprises at least one conductive hole, and the conductive hole penetrates through the wafer substrate; the conductive path forms a pin structure used for being electrically connected with the passive element on the second surface of the wafer through the conductive hole.

Preferably, wherein the conductive path comprises at least one conductive hole, and the conductive hole penetrates through the wafer substrate; the conductive holes are located outside the area of the wafer function area of the wafer; the conductive hole is located at the cutting channel position of the wafer.

Preferably, the conductive path comprises at least one conductive hole, and the conductive hole extends from the lower surface of the power module to the upper surface.

Preferably, the conductive path comprises at least one conductive hole, and the conductive hole is located on the side wall of the power module.

Preferably, the conductive path comprises at least one connective layer, and the connective layer is used for electrically connecting a wafer functional area of the wafer and a power pin of the passive element in a welding or electroplating mode.

Preferably, wherein the first surface, the second surface and the inner wall of the conductive hole of the wafer substrate respectively form a first insulating layer; a second insulating layer is formed on the surface of the wafer functional area, and the second insulating layer is used for blocking SW power pins.

Preferably, the plane size of the power module or the plane size of the passive element is the same as the plane size of the wafer.

Preferably, the passive element is pre-formed, the passive element comprises a passive element functional area and/or a complete power pin, and the passive element is electrically connected with the chip through welding or electroplating, or is electrically connected with the wafer before cutting; and the passive element is plastic-sealed on the second surface of the wafer to form a support.

Preferably, the passive element is grown and formed on the wafer, and is electrically connected with the wafer through sintering or electroplating.

Preferably, the passive element comprises a first passive element and a second passive element, and the wafer, the second passive element and the first passive element are sequentially stacked in the vertical direction.

Preferably, wherein the plane size of the second passive element is the same as the plane size of the wafer.

Preferably, an interconnection is formed between the wafer and the second passive element, and/or, between the second passive element and the first passive element through welding or sintering or electroplating.

Preferably, the wafer comprises a first wafer and a second wafer, and the first wafer, the second wafer and the passive element are sequentially stacked in the vertical direction.

Preferably, the second wafer comprises at least one conductive path, the conductive path penetrates through the substrate of the second wafer, and the conductive path is located in the interior or the side wall of the second wafer.

Preferably, a wafer-level power module comprises:
a wafer, the wafer comprising a wafer functional area, and the wafer functional area being located on a first surface of the wafer;
a passive element, the passive element comprising at least one functional conductive layer and a functional dielectric layer;

The passive element and the wafer are stacked, and the occupied area after stacking is equal to the area of the wafer;

The wafer functional area is electrically connected with the functional conductive layer through a conductive path; at least one part of the conductive path is realized by electroplating a through hole or a semi-through hole; the conductive path is arranged on the side surface or the middle position of the module;

The wafer is attached to or directly attached to the passive element by means of a filling material, and the passive element provides mechanical strength support for the wafer;

The functional dielectric layer is disposed between at least one functional conductive layer of the passive element and a first surface of the wafer.

Preferably, the passive element comprises a first passive element and a second passive element, and the first passive element and the second passive element are vertically stacked on the second surface of the wafer respectively.

Preferably, wherein the passive element is a multi-phase anti-coupling inductor; wherein the multi-phase anti-coupling inductor comprises at least two magnetic units, and windings of the at least two magnetic units share the same magnetic column, so that the lengths of the windings are equal.

Preferably, the input pins and the output pins of the winding of the multi-phase anti-coupling inductor are arranged in a staggered manner; the winding of each phase of the multi-phase anti-coupling inductor is single-turn or multi-turn, and the winding of each phase is of a multi-strand winding structure.

Preferably, the power pin comprises an alternating-current voltage pin and a direct-current voltage pin, the alternating-current voltage pin is located in the middle area of the power module, and the direct-current voltage pin is located on the periphery of the power module.

Preferably, wherein the wafer comprises at least one power region, at least one control area and/or a power management area and/or a data processing area, and the planar size of the wafer is the same as the planar size of the passive element.

Preferably, wherein the wafer comprises two power regions, and the two power regions are interconnected by means of a rewiring layer, wherein the rewiring layer comprises at least one TSV hole, and the TSV hole is located on the side wall of the wafer.

Preferably, an adhesive layer or a metal shielding layer is arranged between the wafer and the passive element.

Preferably, the thickness of the wafer is less than 100 μm.

Preferably, the wafer-level power module comprises a power pin, the power pin is placed on the outer side surface of the passive element, and the first surface of the wafer is between the second surface of the wafer and the passive element.

Preferably, wherein the passive element comprises a capacitor electrically interconnected with a direct-current power pin of the wafer, and/or the passive element comprises a capacitor or a magnetic element electrically interconnected with an alternating-current power pin of the wafer, and/or the passive element comprises a capacitor electrically interconnected with a direct-current pin of the magnetic element.

Preferably, the wafer-level power module further comprises an output capacitor, and the output capacitor integrates pins of the wafer-level power module and is arranged on the lower surface of the wafer-level power module.

Preferably, wherein the wafer-level power module further comprises a silicon wafer capacitor array, and the silicon wafer capacitor array comprises the output capacitor and part of the capacitors required by the wafer during operation.

Preferably, the manufacturing method of the wafer-level power module comprises the following steps:
S1, attaching a plurality of wafers to a jig, thinning the wafers, and tightly combining the wafers with the plurality of passive element layers to form an integrated structure;
S2, through a process such as laser or etching, opening a hole or a semi-through hole, electroplating a through hole or a semi-through hole, and electrically connecting the wafer functional area with the functional conductive layer;
S4, de-paneled to a plurality of modules through a wafer cutting process, then testing and packaging the modules.

Preferably, the manufacturing method, characterized in that step S3 is further included between steps S2 and S4:
S3: thinning the second surface of the wafer.

Preferably, the manufacturing method of the wafer-level power module, the functional conductive layer of the passive element is formed by combining the wafer and the passive element layer into an integrated structure and then electroplating.

Preferably, a method for manufacturing a wafer-level power module, comprising the following steps:
S1: providing a whole wafer;
S2: forming TSV holes on the substrate of the wafer, wherein in the step, the TSV holes do not penetrate through the wafer substrate;
S3: forming a first insulating layer on an inner wall of the TSV hole;
S4: filling a metal in the TSV hole, and forming a first metal layer on a first surface of the wafer substrate;
S5, thinning the second surface of the wafer, exposing the metal in the TSV hole, and leaving the space to the passive element;
S6: providing a passive element on a second surface of the wafer;
S7, scribing to form an independent power module, wherein the plane size of the power module is the same as the plane size of the wafer.

Preferably, the manufacturing method, the step S6 is specifically:
If the passive element is discrete, molding the passive element to form a plastic package body so as to support the wafer, and in step S7, performing scribing and cutting from the first surface of the wafer;
If the passive element is a pre-formed splicing plate, the passive element needs to be fixed with the wafer through filling seam;
the position of the TSV hole is located on a cutting channel of a wafer.

Preferably, the manufacturing method, the step S6 specifically comprises: growing a passive element on the second surface of the wafer.

Preferably, a method for manufacturing a wafer-level power module, comprising the following steps:
S1: providing a whole wafer;
S2, forming a first metal layer on a first surface of the wafer, wherein a first surface of the wafer is a functional surface;
S3, after the first surface of the wafer is fixed on the carrier, thinning the wafer, and leaving the space to the passive element;
S4: forming a TSV hole from a second surface of the wafer to the inside, the TSV hole extending to the first metal layer;
S5: forming a first insulating layer on the inner wall of the TSV hole and the second surface of the wafer;
S6: filling the TSV hole with a metal, and forming a second metal layer on a second surface of the wafer;
S7: providing a passive element on a second surface of the wafer;
S8: scribing to form an independent power module, wherein the plane size of the power module is the same as the plane size of the wafer.

Preferably, the manufacturing method, the step S7 specifically comprises:
If the passive element is discrete, molding the passive element to form a plastic package body so as to support the wafer, and in step S7, performing scribing and cutting from the first surface of the wafer;
If the passive element is a pre-formed splicing plate, the passive element needs to be fixed with the wafer filling seam;
the position of the TSV hole is located on a cutting channel of a wafer.

Preferably, a method for manufacturing a wafer-level power module, comprising the

following steps:
S1: providing a whole wafer;
S2: laying a passive element on a second surface of the wafer;
S3: forming a conductive hole, the conductive hole penetrating through the wafer and the passive element;
S4: forming a first insulating layer in the conductive hole;
S5: drilling a deep drilling hole on the surface of the passive element, and forming a conductive hole with a wider width at one end of the conductive hole;
S6: forming a metal layer on the first surface of the wafer, the surface of the passive element and the conductive hole;
S7: etching: respectively forming required pins on the first surface of the wafer and the surface of the passive element;
S8: scribing is carried out at the position of the conductive hole to form an independent power module, and the plane size of the power module is the same as the plane size of the wafer.

Preferably, a method for manufacturing a wafer-level power module, comprising the following steps:
S1: providing a whole wafer;
S2, laying a passive element on a second surface of the wafer, wherein an internal metal layer is arranged in the passive element;
S3: forming a conductive hole from the first surface of the wafer to the inside, so that the internal metal layer is exposed;
S4: forming a first insulating layer in the conductive hole;
S5: removing part of the first insulating layer located outside the internal metal layer, so that part of the internal metal layer is exposed;
S6: filling metal in the conductive hole, and forming a metal layer on a first surface of the wafer;
S7: etching: forming a required pin on a first surface of the wafer;
S8: scribing at the position of the conductive hole to form an independent power module, the plane size of the power module being the same as the plane size of the wafer.

Compared with the prior art, the application has the following beneficial effects:
(1) According to the application, the passive element is directly connected to the wafer, and compared with the prior art, the wafer is not embedded in the process, so that the waste of the height dimension caused by wafer packaging is omitted, and the size of the embedded wafer packaging is omitted, so that the thickness except the passive element is reduced by 50%.
(2) Due to the fact that the effective functional area of the wafer substrate usually has only less than 10 μm, the thickness of the substrate of the wafer can be very thin; with the passivation layer and the conductive layer on the surface of the substrate, the total thickness can also be controlled within 50 μm, and even the wafer substrate can be controlled to be within 30 μm. Compared with the prior art, the embedding process requires that the thickness of the wafer is at least 150 μm, so that the wafer cannot be damaged in the embedding process; but in this application, the passive element is used to support and fix the wafer, so that the height of the wafer can be very thin and the height of the power module can be greatly reduced. In other words, the thickness of the wafer with the thickness of 30 μm is slightly smaller in the whole power module, basically negligible, the thickness of the finally formed power module is basically consistent with the thickness of the passive element, and the wafer-level power module with the total height smaller than 0.5 mm or even smaller than 0.3 mm can be realized, and the area is equivalent to that of the wafer.
(3) By means of the structure, the thickness of the wafer in the whole module is very small, and it can be used even in the situation that has a high requirement of the size of the module, such as vertical power supply of the data center, power supply of the wearable product and the like.
(4) The passive element is mainly related to the cross-sectional area, and for different application occasions, if the thickness requirement is extremely strict, the plane size of the module can be properly released, so that the plane size of the passive element is increased, and the thickness of the passive element is reduced; and if the plane size is extremely strict, the plane size of the wafer can be properly reduced, the thickness of the passive element is increased, and the design of the whole module is very flexible.

### BRIEF DESCRIPTION OF DRAWINGS

FIG. 1A is a circuit diagram of a power module in the prior art;

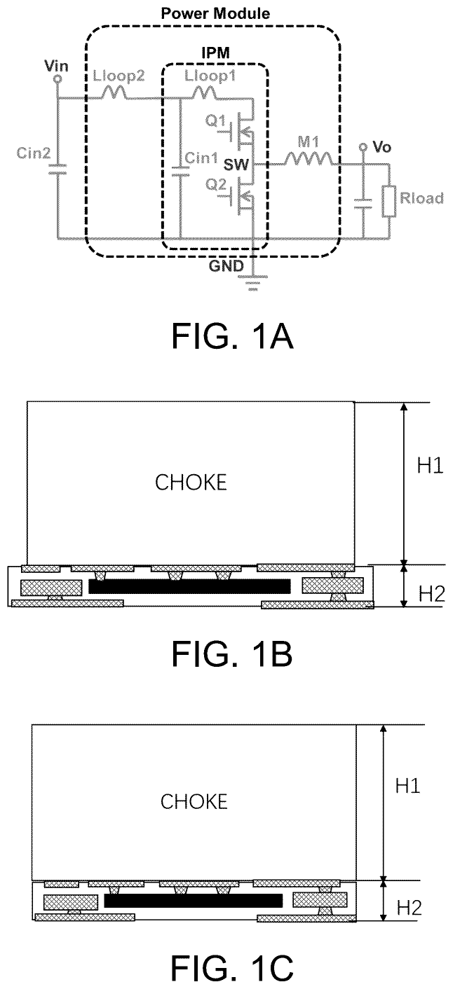

FIG. 1B and FIG. 1C are schematic structural diagrams of a power module in the prior art;

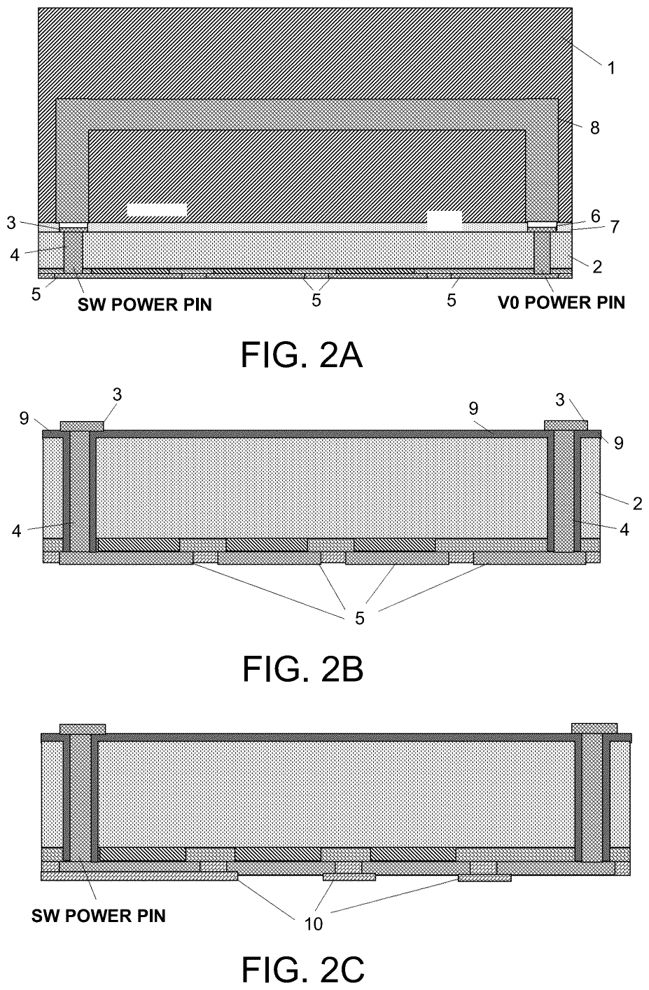

FIG. 2A is a schematic structural diagram of a wafer-level power module according to an embodiment of the present application;

FIG. 2B is a schematic structural diagram of a second metal layer of a wafer-level power module according to an embodiment of the present application;

FIG. 2C is a schematic structural diagram of a second insulating layer of a wafer-level power module according to an embodiment of the present application;

FIG. 2D is a schematic structural diagram of a wafer-level power module according to another embodiment of the present application;

FIG. 3A and FIG. 3B are schematic structural diagrams of a second metal layer and a conductive hole of a wafer-level power module according to another embodiment of the present application;

FIG. 4A and FIG. 4B are schematic structural diagrams of conductive holes of a wafer-level power module according to another embodiment of the present application;

FIG. 4C is a schematic structural diagram of a third metal layer of a wafer-level power module according to an embodiment of the present application;

FIG. 5 is a schematic structural diagram of a first wafer and a second wafer of a wafer-level power module according to an embodiment of the present application;

FIG. 6A to FIG. 6E are schematic structural diagrams of a winding of a passive element of a wafer-level power module according to an embodiment of the present application;

FIG. 7A to FIG. 7C are schematic structural diagrams of power pins of a wafer-level power module according to an embodiment of the present application;

FIG. 8 is a schematic structural diagram of a first passive element and a second passive element of a wafer-level power module according to an embodiment of the present application;

FIG. 9 is a schematic structural diagram of a first passive element and a second passive element of a wafer-level power module according to another embodiment of the present application;

FIG. 10A to FIG. 10C are schematic structural diagrams of a wafer-level power module according to another embodiment of the present application;

FIG. 11A and FIG. 11B are schematic structural diagrams of a wafer-level power module according to another embodiment of the present application;

FIG. 12 is a schematic structural diagram of a metal shielding layer of a wafer-level power module according to an embodiment of the present application;

FIG. 13A to FIG. 13F are schematic flow diagrams of a manufacturing method of a wafer-level power module according to an embodiment of the present application;

FIG. 14A to FIG. 14F are schematic flow diagrams of a manufacturing method of a wafer-level power module according to another embodiment of the present application;

FIG. 15A to FIG. 15E are schematic flow diagrams of a method for manufacturing a wafer-level power module according to another embodiment of the present application.

### DESCRIPTION OF EMBODIMENTS

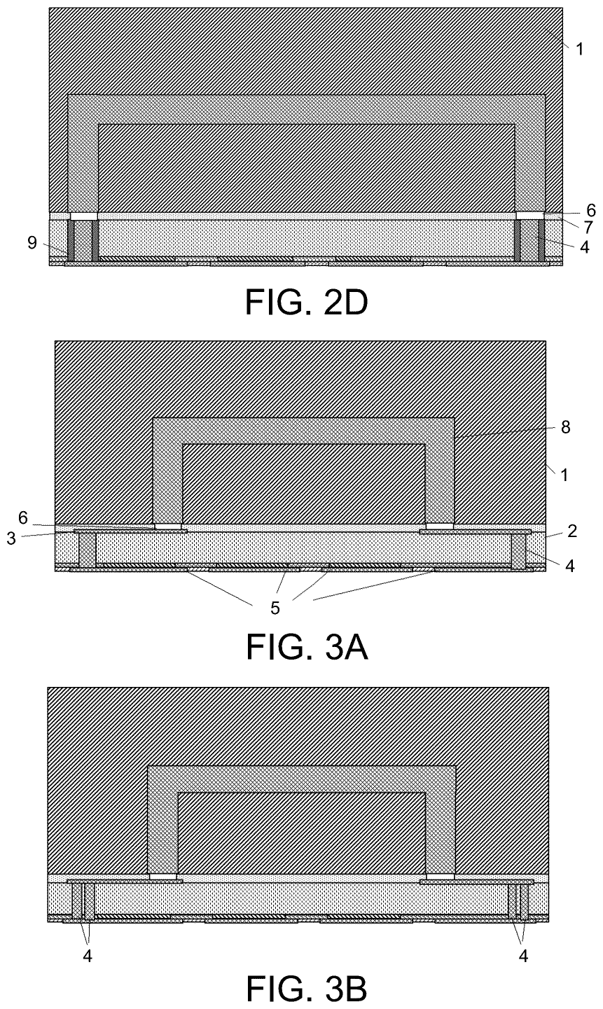

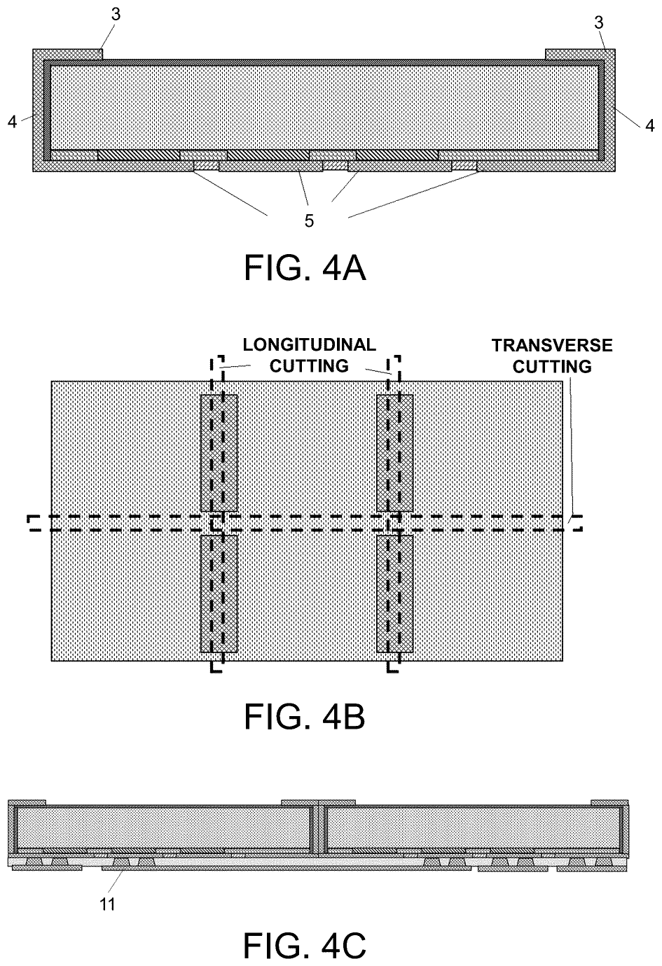

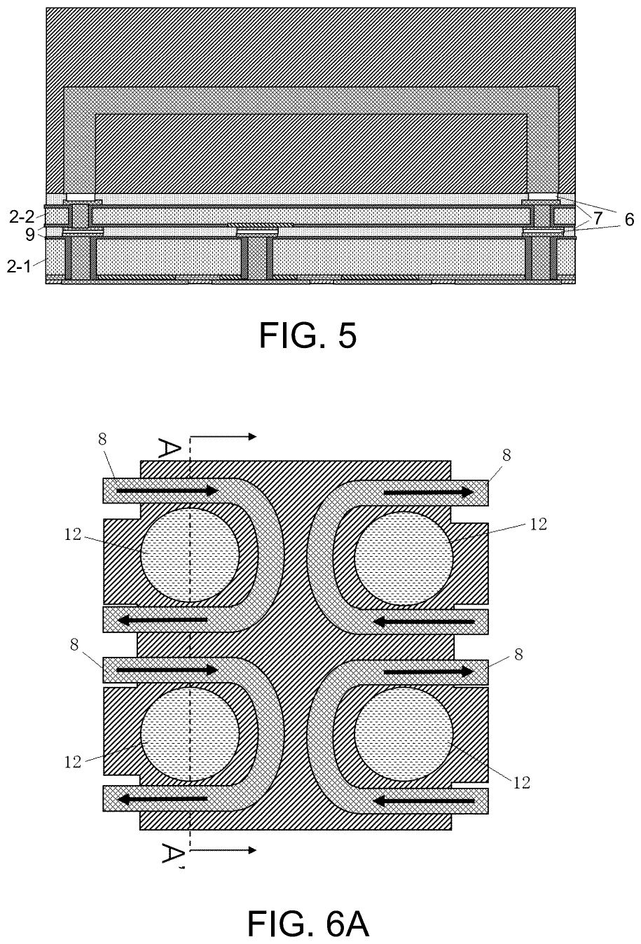

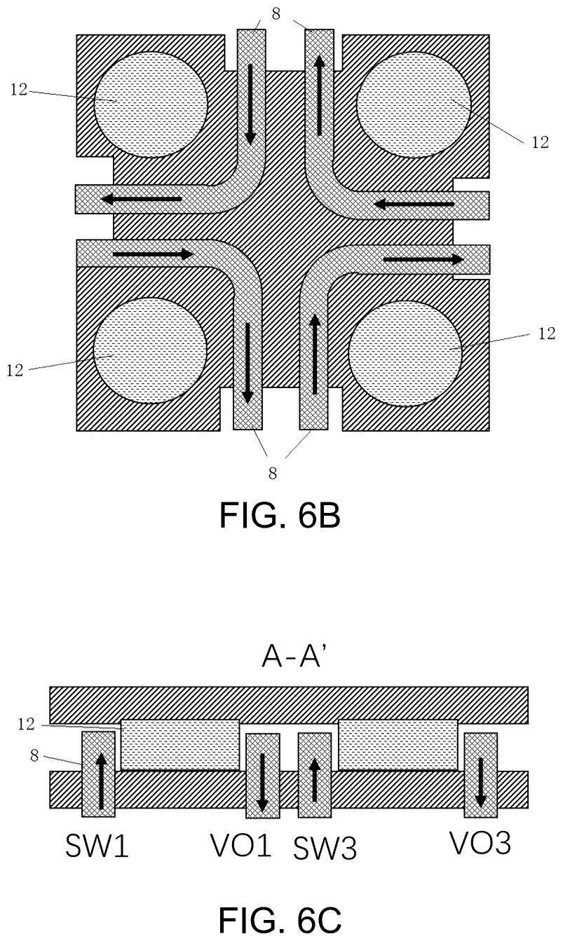

The embodiment of the application discloses a wafer-level power module. As shown in FIG. 2A, the wafer-level power module comprises a wafer 2 and a passive element 1, the wafer 2 comprises a wafer functional area, and the wafer functional area is located on the first surface (the lower surface of the wafer 2) of the wafer 2; the passive element 1 comprises at least one power pin, the passive element 1 is stacked on the second surface (the upper surface of the wafer) of the wafer 2, the wafer functional area is electrically connected to the second surface of the wafer 2 from the first surface of the wafer 2 through a conductive path and is electrically connected with the power pin of the passive element 1, and the wafer functional area comprises a first metal layer 5; the conductive path is attached to the wafer 2, the conductive path forms a pin structure on the second surface of the wafer 2 which is used for being electrically connected with the passive element 1 through the conductive hole 4, the pin structure is a second metal layer 3, the bonding layer 7 is arranged between the wafer 2 and the passive element 1. The conductive path is placed on the side face or the middle position of the module, part or all of the conductive path is achieved through the through hole or the semi-through hole being electroplated, the welding point of the module can be reduced, and extremely high reliability is achieved.

As shown in FIG. 2A, in the embodiment, the passive element 1 is a magnetic element and comprises a magnetic core body and a winding 8, the first end and the second end of the winding 8 of the passive element 1 are both connected to the second metal layer 3 of the wafer 2 through a connecting layer 6. The plane size (x, y) of the second metal layer 3 is the same as the plane size (x, y) of the passive element 1, here, “the same” can be defined as the size deviation of the two being controlled within 0-100 μm. Since the power module is formed by cutting the wafer, the plane size of the power module is the plane size of the wafer 2. The SW power pin of the power module is connected with the first end of the winding 8 through the conductive path and through the connecting layer 6, and the VO power pin is connected with the second end of the winding 8 through the conductive path and through the connecting layer 6. Due to the fact that the wafer 2 is thin, it is easily damaged by the external force; so that a bonding layer 7 is arranged between the wafer 2 and the passive element 1, the passive element 1 can be firmly bound with the wafer 2, and due to the fact that the thickness of the passive element 1 is large, the wafer 2 which is relatively weak is not bent depending on the support of the passive element 1. Furthermore, the sufficient flatness of pins of the power module can be ensured.

In order to realize the connection between the wafer 2 and the passive element 1, the pin located on the back face of the wafer 2 can be the second metal layer 3, and the pin located on the back face is connected with the pin of the passive element 1 through the connecting layer 6; or the pin located on the back face can be bump or ball planting on the second metal layer 3, and then is connected with the winding 8 of the passive element 1.

The pin of the power module can be directly realized by the solder mask layer on the first metal layer 5, or can be a planted bump or ball.

Compared with the prior art, the structure of the embodiment of the application is that the passive element 1 is directly connected to the wafer 2, the wafer 2 does not pass through the embedding process, and the waste of the height dimension caused by the packaging of the wafer 2 is omitted. According to the structure of the prior art, the thickness of the required wafer 2 is at least 150 μm, and if the wafer 2 is packaged, only one metal layer and an insulating layer are arranged on each of the upper layer and the lower layer, and the thickness is at least 150 μm. That is to say, the thickness of the total substrate is 300 μm. According to the embodiment of the application, the size of the embedded packaging is omitted, so that the thickness except the passive element 1 is reduced by 50%.

In some embodiments, the passive element 1 is mainly related to the sectional area, and for different application occasions, if the thickness requirement is extremely strict, the plane size of the power module can be properly released, so that the plane size of the passive element 1 is increased, and the thickness of the passive element 1 is reduced; and if the plane size is extremely strict, the plane size of the wafer 2 can be properly reduced, the thickness of the passive element 1 is increased, and therefore the whole power module is very flexible in design.

In a preferred embodiment, the thickness of the wafer 2 is less than 100 μm or even less than 50 μm. Due to the fact that the height on the wafer functional area of the wafer 2 substrate is often less than 10 μm, the thickness of the substrate of the wafer 2 can be very thin, and with the passivation layer and the conductive path on the surface of the substrate the height can be controlled within 50 μm or even within 30 μm. Compared with the prior art, the thickness of the wafer 2 is required at least 150 μm in the embedding process, so that the wafer 2 cannot be damaged in the embedding process, and the wafer 2 can be fixed and supported by the passive element 1, so that the height of the wafer 2 can be thinner and the height of the power module can be greatly reduced. In other words, the thickness of the wafer 2 with the thickness of 30 μm is slightly smaller in the whole power module, it is basically negligible, the thickness of the finally formed power module is basically consistent with the thickness of the passive element 1, and the WLCSM (Wafer Level Chip Size Module) with the total height smaller than 0.5 mm or even smaller than 0.3 mm and with the same size of the wafer 2 can be achieved.

According to the structure of the embodiment of the application, the thickness of the wafer 2 in the whole power module is very small, and the thickness of the wafer 2 can even be ignored. In particular, occasions with high requirements on the size of the power module, such as vertical power supply of the data center, power supply of the wearable product and the like.

In a preferred embodiment, a first insulating layer 9 is respectively formed on the first surface, on the second surface and the inner wall of the conductive hole 4 of the wafer 2 substrate. As shown in FIG. 2B, as the substrate is a semiconductor and between the conductor and the insulator, the first insulating layer 9 is formed on the inner wall of the conductive hole 4 and the first surface and the second surface of the wafer 2 substrate to realize electrical insulation between the conductive hole 4 and the substrate and between the second metal layer 3 and the substrate. The conductive hole 4 can be a through hole or a semi-through hole formed by laser of etching, and the through hole or the semi-through hole is electroplated, so that the wafer functional area and the functional conductive layer are electrically connected; or the electrical connection between the wafer functional area and the functional conductive layer can also be realized through wiring.

In a preferred embodiment, a metal diffusion barrier layer is further provided in the conductive hole 4, the metal diffusion barrier layer is located on the inner side of the first insulating layer 9, the metal diffusion barrier layer is located between the first insulating layer 9 and the conductive hole 4, and the purpose of the metal diffusion barrier layer is to further prevent the copper atom from diffusing to the substrate at a high temperature (such as 400° C.), thereby preventing a channel from being formed between the conductive hole 4 and the substrate. Ti, Ta, TaN and TiN can be used for manufacturing the metal diffusion barrier layer, and the material of the first insulation layer 9 comprises silicon dioxide (SiO2) or silicon nitride (Si3N4) and the like.

In some other embodiments, a second insulating layer 10 is formed on the surface of the wafer functional area, and the second insulating layer 10 is used for blocking an SW power pin. As shown in FIG. 2C, due to the fact that the SW power pin is an intermediate point and it has a jumping voltage, the SW power pin is generally not led out, and therefore a second insulating layer 10 is arranged on the surface of the first metal layer 5 to realize insulation between the power module and the system board. In this way, the system board is more flexible when wiring is carried out, and the intermediate point does not need to be avoided.

In some other embodiments, the second metal layer 3 is omitted on the second surface of the wafer 2, so that the conductive hole 4 can be directly connected with the passive element 1 through the connecting layer 6 to obtain the structure shown in FIG. 2D. Compared with FIG. 2B, the first insulating layer 9 does not exist on the second surface of the wafer 2. The implementation of the structure can be based on the structure of FIG. 2B. The mechanically grinding is processing on the second surface of the wafer 2, the second metal layer 3 and the first insulating layer 9 located on the second surface of the wafer 2 are removed, and even the substrate layer can be continuously grinding and made it thinner. The insulation between the passive element 1 and the substrate can be realized by the adhesive layer 7. Therefore, the adhesive layer 7 not only plays an electrical insulation role, but also plays a role in fixing and supporting the wafer 2. The second surface of the wafer 2 represent not only the initial surface of the substrate processing, but also the surface after mechanical grinding to thin the substrate of the wafer 2, and the thinned surface may also be referred to as a second surface.

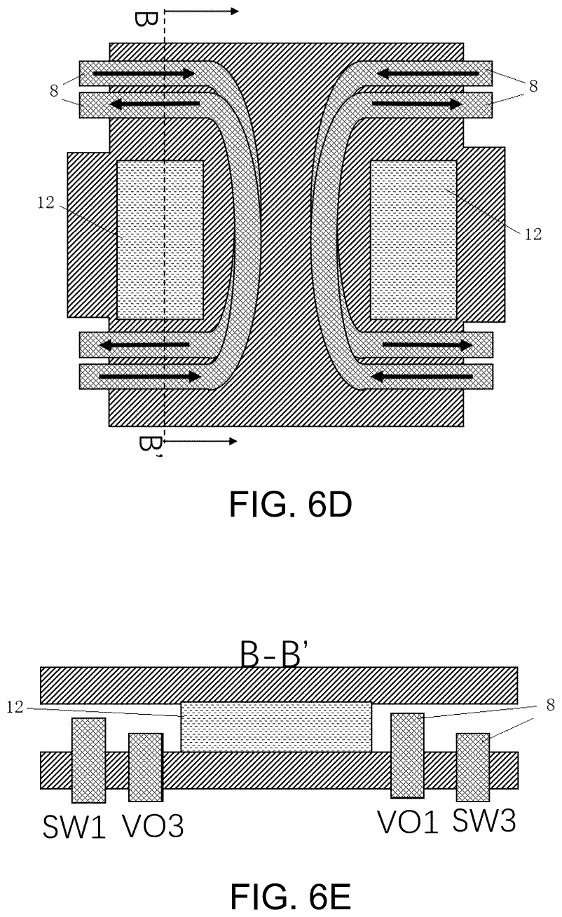

In some other embodiments, the conduction circuit structure can also be as shown in FIG. 3A, the conductive hole 4 is located on the periphery of the first wafer 2-1, and the first end and the second end of the winding 8 of the passive element I are close to the middle area, and the first wafer 2-1 is connected with the passive element 1 through the second metal layer 3. In combination with the foregoing several embodiments, it can be clearly seen that the conductive hole 4 of the first wafer 2-1 and the winding 8 pin of the passive element I can be distributed more freely and are not constrained with each other by means of the second metal layer 3. A capacitor 13 or an inductor is directly arranged on the first wafer 2-1, and the transition wire between them can still be carried out through the second metal layer 3.

In a preferred embodiment, since the diameter of the conductive hole 4 is relatively small, because one end of the winding 8 needs to be connected to the plurality of conductive holes 4, a smaller on-resistance is achieved, as shown in FIG. 3B.

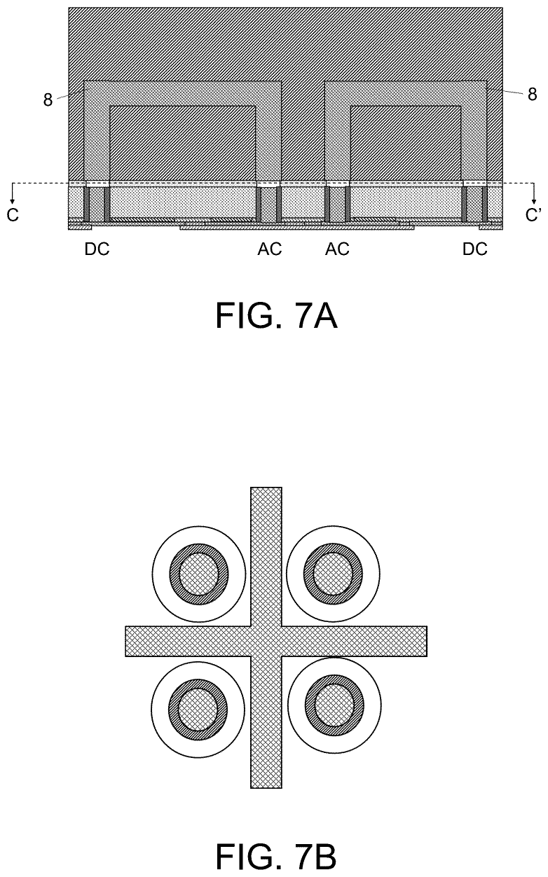

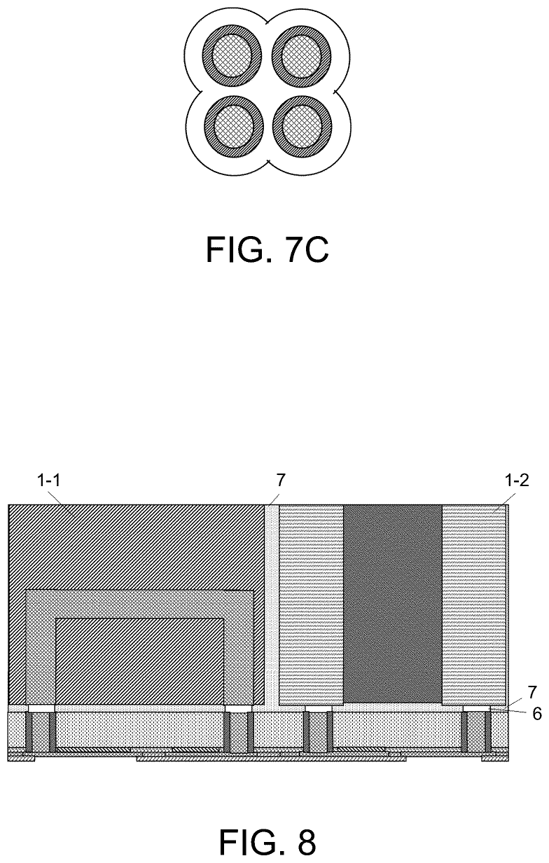

In some other embodiments, the conductive hole 4 is located at the cutting channel position of the wafer, as shown in FIG. 4A, the conductive hole 4 is arranged on the side wall of the wafer 2, and then extends to the first metal layer 5 and the second metal layer 3 on the wafer 2 to form two external end faces. The structure does not occupy the internal space of the substrate, so that the utilization rate of the wafer 2 can be higher, and especially for application occasions with high pin density. Due to the problems of precision and pollution of the chip digging holes, the chip functional area can be damaged, for example, in the rapid and low-cost laser opening process, and the light can diffract and damage the functional area. Therefore, a large avoiding distance is often required. If the desired precision is high and the pollution is small, an expensive dry etching process is needed. As shown in FIG. 4B, the conductive hole 4 is formed on the cutting channel of the whole wafer, and after scribing, the two halves of the conductive hole 4 are distributed to two adjacent units, and the metal on the two sides of the middle wafer unit in FIG.

4B is the side metal on the left side and the right side shown in FIG. 4A. Therefore, in contrast, the occupied area of the conductive hole 4 can be further reduced in this embodiment. Due to the fact that the cutting channel of the wafer exists originally, the functional area only needs to be avoided on one side of the via hole.

The conductive hole 4 shown in FIG. 4B is square, and certainly can also be a circular array, an ellipse and the like, which is not limited herein.

For FIG. 4B, the wafer unit may be a plurality of switches connected in parallel or in series, and the corresponding cutting mode may be that the two wafer units are integrally cut, or the four wafer units are a whole, or six wafer units are integrated.

To realize interconnection of each wafer unit, a third metal layer 11 can be continuously grown on the periphery of the first metal layer 5 of each wafer unit, and the third metal layer 11 is interconnected with a plurality of units to realize a complete multi-phase circuit, as shown in FIG. 4C.

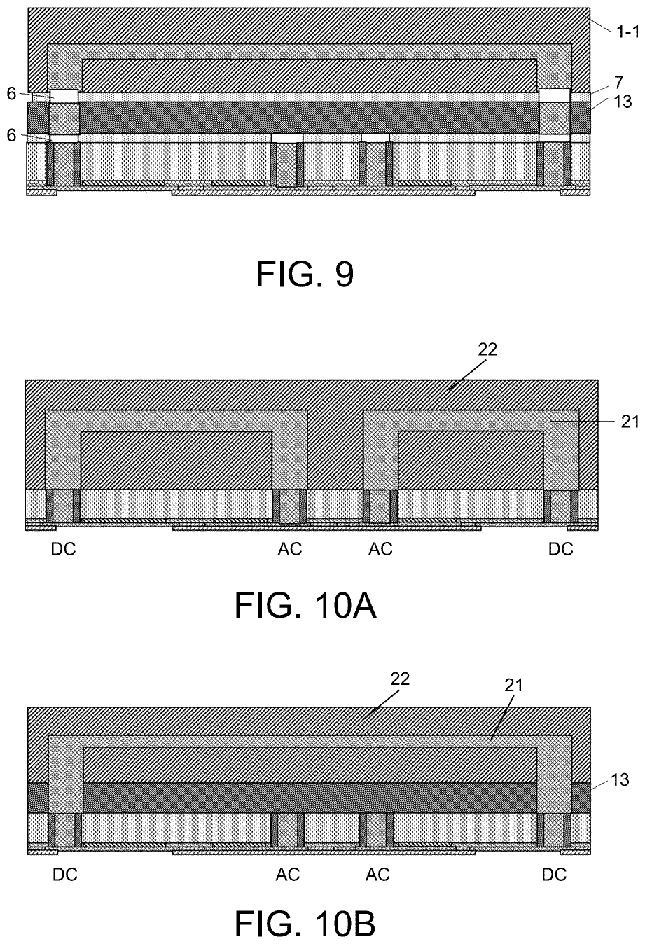

In some other embodiments, the wafer 2 includes a first wafer 2-1 and a second wafer 2-2, as shown in FIG. 5, a second wafer 2-2 is disposed between the first wafer 2-1 and the passive element 1, such as a first wafer 2-1 is defined as a switch device with driving and the second wafer 2-2 is defined as a controller device. In addition to the main power switch (including the drive) and the passive element 1, the power module of the present application can also be integrated with a control function. Therefore, the connection between the control device and the switch device can be solved inner the power module, the pins of the whole power module are reduced, and the use of customers is more flexible and convenient. In order to enhance the reliability among the first wafer 2-1, the second wafer 2-2 and the passive element 1, the adhesive layer 7 is arranged between them. The first end of the winding 8 can be connected with the conductive path of the second wafer 2-2 through the connecting layer 6, then it is connected with the conductive path of the first wafer 2-1 through the second wafer 2-2, and finally power pin of an alternating voltage (taking SW as an example) and power pin of a direct current voltage (taking Vo as an example) are formed at the bottom of the power module.

In some other embodiments, the passive element 1 is a multi-phase integrated inductor, the inductor structure is a four-phase coupling inductor or a coupling transformer, the multi-phase integrated inductor comprises at least two magnetic units, and windings 8 of the at least two magnetic units share the same magnetic column 12, so that the lengths of the winding 8 are equal.

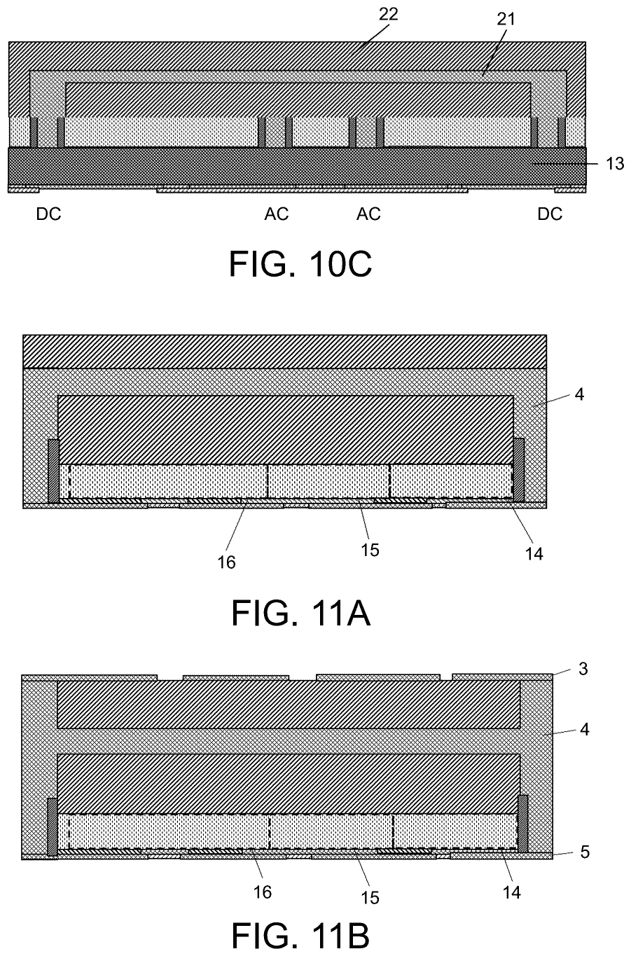

The input pins and the output pins of the winding 8 of the multi-phase integrated inductor are arranged in a staggered manner, taking FIG. 6A as an example, the cross-sectional structure along the A-A′ direction is shown in FIG. 6C, the formed pins can be in an alternating arrangement of alternating-current/direct-current (such as SW1 -VO1 -SW3 -VO3), and the pins of the corresponding power module are also arranged in a staggered manner.

In a preferred embodiment, the winding 8 of each phase of the multi-phase integrated inductor is single-turn or multi-turn, the winding 8 of each phase of the multi-phase integrated inductor is a multi-strand winding structure, as shown in FIG. 6D, in order to achieve a better coupling effect and better dynamic characteristics, the windings 8 wound around two magnetic column 12 share one magnetic column 12. As shown in FIG. 6E, SW and VO are arranged in a non-staggered mode and are mainly used for enabling the lengths of the two windings 8 to be approximately equal, so that the current sharing effect is better. It should be noted that each winding 8 can be a single turn or multiple turns or multiple-strand winding; and the multi-phase inductor can also be a multi-phase non-coupled inductor and a multi-winding transformer, and details are not described herein again.

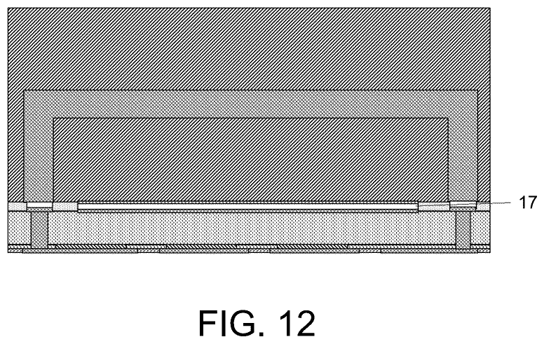

In some other embodiments, the power pins of the power module are distributed on at least one surface of the upper surface and the lower surface of the power module, the power pins comprise an alternating-current voltage pin and a direct-current voltage pin, the alternating-current voltage pin is located in the middle area of the power module, the direct-current voltage pin is located on the periphery of the power module, as shown in FIG. 7A, the pin of the alternating-current voltage is located in the middle of the power module, and the pin of the direct-current voltage is located at the edge of the power module.

Compared with the embodiment, the advantages of the embodiment are that the pin of the direct-current voltage is located at the edge to facilitate the client wiring, and the alternating-current voltage pin is arranged in the middle area, so that the direct-current part cannot be hindered from leading to the external lead, and the use of the client is very flexible.

The conductive hole 4 can be formed by laser drilling and re-electroplating, the cost of the laser drilling is much lower than that of dry etching, but the energy of the laser drilling is relatively large, and the damage to the functional area is obvious. By adopting the structure of the embodiment, the alternating-current voltage pins are arranged in the middle position of the power module, and compared with dispersed arrangement, the centralized arrangement mode can greatly reduce the occupied area of the alternating-current voltage pins, as shown in FIG. 7B. In other words, if the conductive holes 4 are dispersedly arranged, the occupied area of a safe area is needed according to each conductive hole 4, the occupied area of the safety area of the multiple holes is very large, and centralized arrangement is achieved, so that all the holes only need one safe area.

It should be noted that the device stacked above the wafer 2 may be a passive element 1, such as an inductor, a transformer, a capacitor 13, or the like.

In some other embodiments, the passive element 1 comprises a first passive element 1-1 and a second passive element 1-2, and the first passive element 1-1 and the second passive element 1-2 are respectively vertically stacked on the second surface of the wafer 2. As shown in

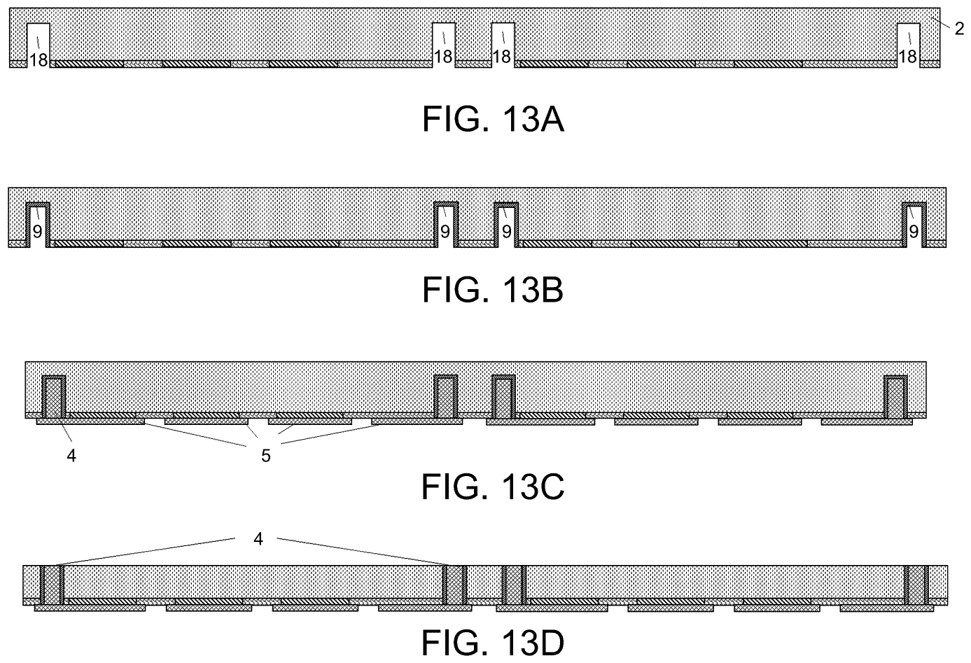

FIG. 8, an inductor and a capacitor 13 can be placed above the wafer 2 to form a complete closed loop. For the Buck circuit, the capacitor 13 is an input capacitor; for the Boost, the capacitor 13 is an output capacitor. When multiple elements are placed on the wafer 2, gaps between the elements should be filled with a filling material, such as the same adhesive material, thereby avoiding stress is applied on the wafer 2.

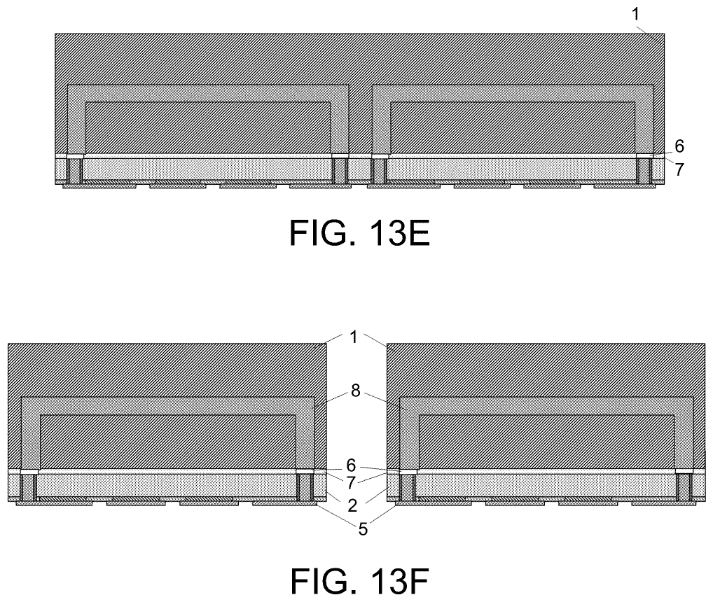

In some other embodiments, the wafer 2, the second passive element 1-2 and the first passive element 1-1 are sequentially stacked in the vertical direction, the plane size of the second passive element 1-2 is the same as the plane size of the wafer 2, and the wafer 2 and the second passive element 1-2, the second passive element 1-2 and the first passive element 1-1 are respectively connected through welding to form interconnection. As shown in FIG. 9, the capacitor 13 can be laid on the wafer 2, and then the inductor is laid. Therefore, the capacitor 13 layer is located between the inductor and the wafer 2 to form a complete closed loop. Compared with FIG. 8, the horizontal area of the capacitor 13 is equivalent to the area of the wafer 2, so that the capacitance value of the capacitor 13 can be large, and the decoupling requirement of the power module is fully met. As close as possible of the two capacitive electrodes, the input loop can be made small, and the loop inductance is reduced. In order to reduce the loop inductance, the capacitor 13 is close to the wafer 2, and the magnetic element is above the capacitor 13. Therefore, the capacitor 13 not only has a capacitor electrode, but also a transition electrode for assisting the interconnection of the magnetic element and the wafer 2. In the embodiment disclosed by the application, the capacitor 13 can be a silicon wafer capacitor array, and the silicon wafer capacitor array comprises a part of capacitance required by an output capacitor and/or a wafer during working.

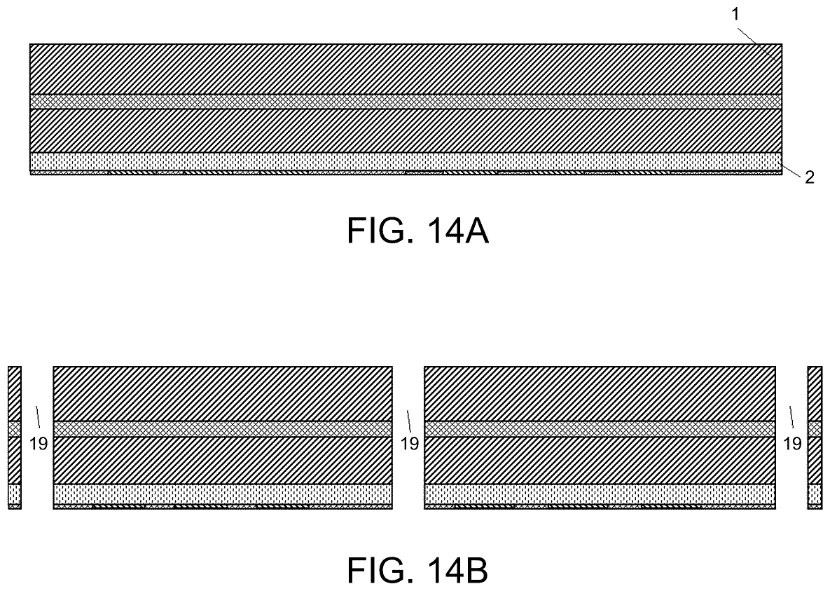

As shown in FIG. 10A and FIG. 10B, each passive element 1 in the foregoing embodiment may be pre-formed and then stacked on the wafer 2. However, the stacking precision causes a large aperture, or a back surface copper spreading pad is required, And process complexity and space waste are caused. According to the embodiment of the application, a functional conductive layer 21 can be formed by taking a wafer 2 as a carrier and growing a required magnetic element or a capacitive element (collectively passive devices) on the back surface of the wafer 2; and at least one functional dielectric layer 22 is arranged adjacent to the functional conductive layer 21, wherein the functional dielectric layer can be provided with a magnetic material of a magnetic element or a dielectric material of a capacitor. Alternatively, a passive device having a semi-formed (functional region, but not yet a complete lead-out electrode) is connected to the wafer 2 by electroplating. In this way, the interconnection is realized through the wafer semiconductor process, that is, the electrical interconnection of the wafer 2 and the passive device is carried out through drilling and electroplating processes. Precision, space utilization rate, reliability and even production efficiency are greatly improved. In the embodiment shown in FIG. 10C, the same process manufacturing method can be adopted, the capacitor 13 is arranged on the bottom surface of the wafer 2, and the pins of the capacitor 13 are integrated with the power pins of the power module and are both arranged on the lower surface of the power module.

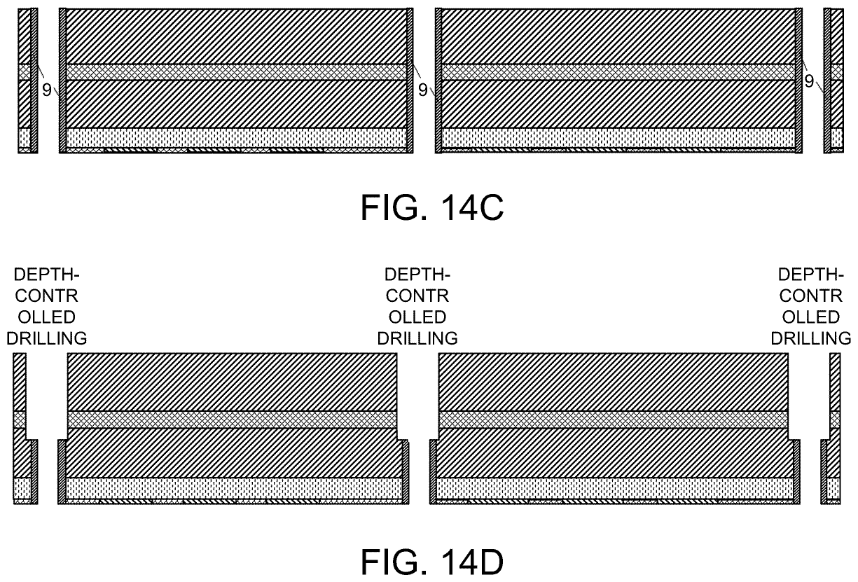

By comparing the several embodiments, it can be clearly seen that the connection between the capacitor 13 and the wafer 2 or the connection between the inductor and the capacitor 13 can not only be welded due to the material of the connection layer 6 is different from the material of the conductive hole 4; or the connection layer 6 can be grown from bottom to top on the body of the wafer 2 due to the connection layer 6 is made of the same material as the conductive hole 4. As shown in FIG. 11A, a complete functional power module is manufactured by using a wafer process, but is not limited to a power supply power module. For example, a radio frequency power amplifier, a filter and even an antenna are arranged on the back surface, that is, the power module is formed by cutting a wafer process, and the plane size of the power module is the plane size of the wafer 2; and in the power module, the space is provided for the passive device as much as possible, that is, the thickness of the wafer 2 is as thin as possible, and 100 μm or even 50 μm or less.

In addition to the manufacturing method of the wafer-level power module, the area of the wafer 2 is equivalent to that of the passive device. There are two methods: firstly, the working frequency of the power region 14 of the wafer 2 is above 20 MHz or even more than 100 MHZ, that is, the area of the passive device is reduced, so that the area of the passive device is equivalent to the area of the wafer 2; and secondly, more non-power functions such as a control area 15 and a power management area 16 are integrated in the wafer 2 as much as possible, and the power management area 16 is an intelligent management function of the power supply power module, namely Power Management or other digital management and data processing functions, so that the area of the wafer 2 is equivalent to the area of the passive device. In some other embodiments, the wafer 2 may include two power regions 14 interconnected by a rewiring layer, the rewiring layer including at least one TSV hole located on a sidewall of the wafer.

In a preferred embodiment, as shown in FIG. 11B, the wafer functional area is electrically connected to the top surface of the power module, so that double-sided Pinout or double-sided wiring is realized, and the pin distribution is relatively flexible. Meanwhile, the heat dissipation effect is also improved. More functions may also be provided, such as the top wiring being arranged as an antenna for radio frequency transmission and reception.

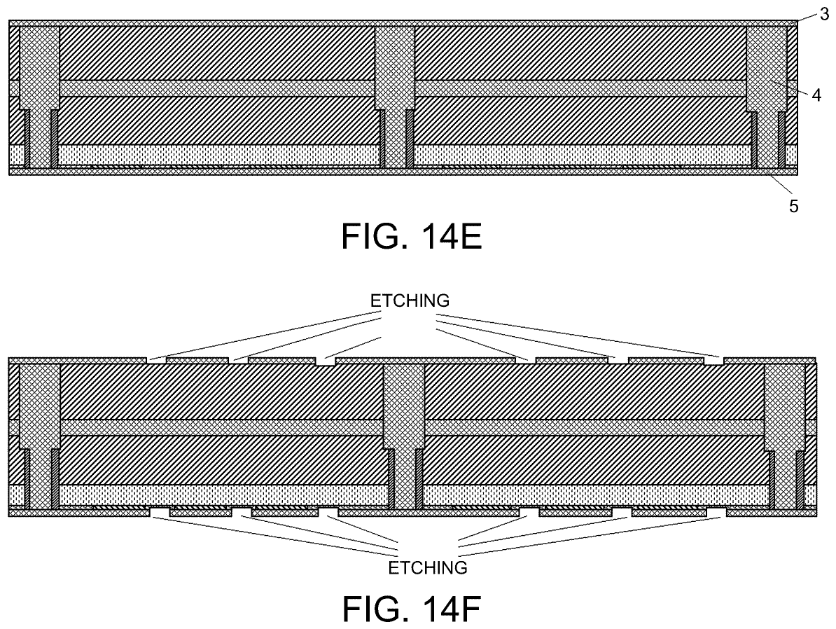

In some other embodiments, as shown in FIG. 12, a structural support is provided between the passive element 1 and the wafer 2, especially for the thinner wafer 2, and the mechanical strength thereof can be reinforced in this manner. The metal shielding layer 17 in the supporting piece can play a shielding role to isolate the inductor and the chip, so that the wafer 2 is prevented from being subjected to electromagnetic interference.

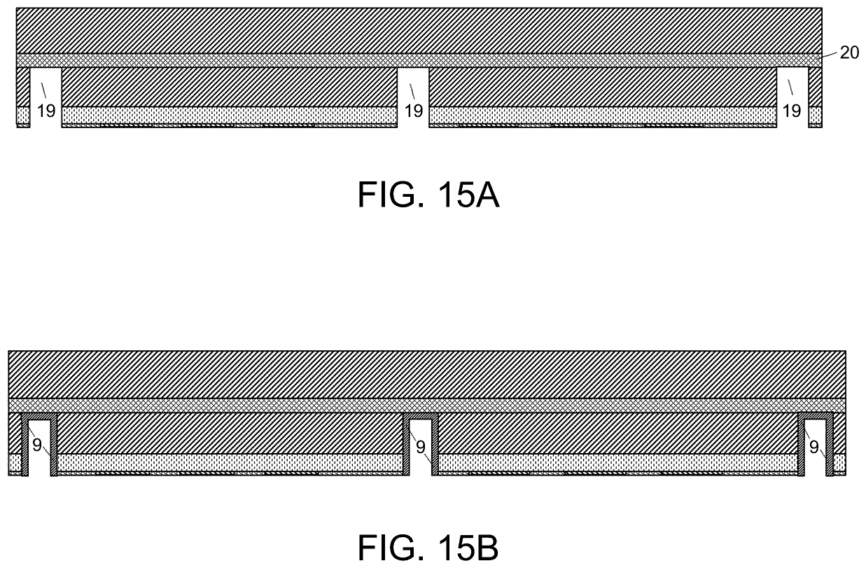

FIG. 13A to FIG. 13F illustrate a method for manufacturing a wafer-level power module according to an embodiment of the present application:
S1: providing a whole wafer;
S2, forming TSV holes 18 on the substrate of the wafer, wherein the TSV holes 18 do not penetrate through the wafer substrate in the step, as shown in FIG. 13A;
S3, forming a first insulating layer 9 on the inner wall of the TSV hole 18, as shown in FIG. 13B;
S4, filling the TSV hole 18 with metal, and forming a first metal layer 5 on the first surface of the wafer substrate, as shown in FIG. 13C;
S5, thinning the second surface of the wafer, exposing the metal in the TSV hole 18, and leaving the space to the passive element 1, as shown in FIG. 13D;
S6: providing a passive element 1 on a second surface of the wafer, as shown in FIG. 13E;
S7, scribing to form an independent power module, wherein the plane size of the power module is the same as the plane size of the wafer 2, and as shown in FIG. 13F, a power module structure as shown in FIG. 2D is formed.

It should be noted that in step S2, the formation mode of the TSV hole 18 is usually dry etching or laser drilling;
In a preferred embodiment, step S6 is specifically:
If the passive element 1 is discrete, performing plastic packaging on the passive element 1 to form a plastic package body so as to support the wafer, and in step S7, performing scribing and cutting from the first surface of the wafer;
If the passive element 1 is a preformed splicing plate, the passive element 1 and the wafer need to be fixed through filling the gap between them.

In a preferred embodiment, the step S6 is specifically as follows: the second surface of the wafer is grown to form the passive element 1.

Optionally, the power module structure shown in FIG. 2A is formed by the following manufacturing method:
S1: providing a whole wafer;
S2, forming a first metal layer 5 on the first surface of the wafer, the first surface of the wafer being a functional surface;
S3, after the first surface of the wafer is fixed on the carrier, thinning the wafer, and leaving the space to the passive element 1;
S4: forming a TSV hole 18 from a second surface of the wafer to the inside, the TSV hole 18 extending to the first metal layer 5;
S5: forming a first insulating layer 9 on the inner wall of the TSV hole 18 and the second surface of the wafer;
S6: filling the TSV hole 18 with metal, and forming a second metal layer 3 on the second surface of the wafer;
S7: providing a passive element 1 on a second surface of the wafer;
S8, scribing to form an independent power module, wherein the plane size of the power module is the same as the plane size of the wafer.

On the basis of the manufacturing method, when the positions of the TSV holes 18 can be located on the cutting channels between the wafer units, a power module structure as shown in FIG. 4A can be manufactured.

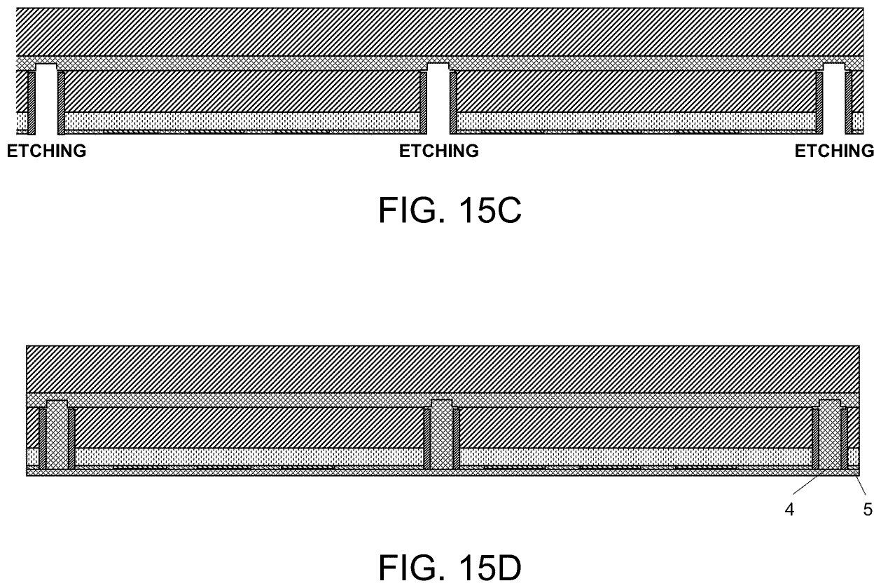

FIG. 14A to FIG. 14F illustrate a method for manufacturing a wafer-level power module according to another embodiment of the present application:
S1: providing a whole wafer;
S2: laying a passive element 1 on a second surface of the wafer, as shown in FIG. 14A;
S3, forming a through hole 19, the through hole 19 penetrating through the wafer and the passive element 1, as shown in FIG. 14B;
S4: forming a first insulating layer 9 in the via hole 19, as shown in FIG. 14C;
S5, a deep drilling hole is drilled on the surface of the passive element 1, a conductive hole 19 with a wider width is formed at one end of the conductive hole 19, as shown in FIG. 14D, in the step, the first insulating layer 9 at the wider conductive hole 19 is removed;
S6, forming a metal layer on the first surface of the wafer, the surface of the passive element 1 and inner the through hole 19, as shown in FIG. 14E;
S7: etching: respectively forming required pins on the first surface of the wafer and the surface of the passive element 1, as shown in FIG. 14F;
S8, scribing is carried out from the position of the conductive hole 19 to form an independent power module, and the plane size of the power module is the same as the plane size of the wafer 2 so as to form the power module structure shown in FIG. 11B.

It should be noted that in step S2, the passive element 1 may have an inductor, a capacitor 13, a transformer, etc., and the laying of the passive element 1 may be a process such as low-temperature sintering ceramic and CVD vapor deposition with LTCC.

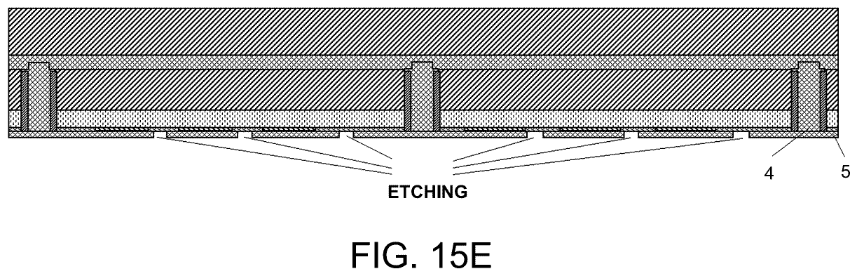

FIG. 15A to FIG. 15E show a manufacturing method of a wafer-level power module in another embodiment of the present application:
S1: providing a whole wafer;
S2, laying a passive element 1 on a second surface of the wafer, wherein an internal metal layer 20 is arranged in the passive element 1;
S3, forming a conductive hole 19 from the first surface of the wafer to the inside, so that the inner metal layer 20 is exposed, as shown in FIG. 15A;
S4: forming a first insulating layer 9 in the conductive hole 19, as shown in FIG. 15B;
S5, removing part of the first insulating layer 9 located outside the internal metal layer 20, so that part of the internal metal layer 20 is exposed, as shown in FIG. 15C;
S6, filling metal in the conductive hole 19, and forming a metal layer on the first surface of the wafer, as shown in FIG. 15E;
S7: etching: forming a required pin on the first surface of the wafer, as shown in FIG. 15E;
S8, scribing is carried out from the position of the conductive hole 19 to form an independent power module, and the plane size of the power module is the same as the plane size of the wafer 2 so as to form the power module structure shown in FIG. 11A.

It should be noted that in step S7, etching can also be performed in a chemical manner by means of laser etching.

The steps S6 and S7 may also be combined into a process, that is, a fully-added metallization mode is used, and after step S5, a metal wiring layer having a pattern is formed on the first surface of the wafer by means of direct electroplating, and the pattern represents different pins.

The “equal” or “same” or “equal to” disclosed by the application needs to consider

the parameter distribution of engineering, and the error distribution is within +/−30%; the two line segments or the two straight lines are defined as the two line segments or the included angle between the two line segments or the two straight lines is less than or equal to 45 degrees; the included angle between the two line segments or the two straight lines is within the range of [60, 120]; and the definition of the phase error phase also needs to consider the parameter distribution of the project, and the error distribution of the phase error degree is within +/−30%.

What is claimed is:

1. A wafer-level power module comprises:
a wafer, the wafer comprising a wafer functional area, and the wafer functional area being located on a first surface of the wafer;
a passive element comprising at least one power pin, wherein the passive element is stacked on a second surface of the wafer, and the wafer functional area is electrically connected to the second surface of the wafer from the first surface of the wafer through a conductive path and is electrically connected with the power pin of the passive element; and
the conductive path is attached to the wafer.

2. The wafer-level power module of claim 1, wherein the conductive path comprises at least one conductive hole, and the conductive hole penetrates through a substrate of the wafer, and the conductive path forms a pin structure used for being electrically connected with the passive element on the second surface of the wafer through the conductive hole.

3. The wafer-level power module of claim 1, wherein the conductive path comprises at least one conductive hole, and the conductive hole penetrates through a substrate of the wafer, the conductive hole is located outside an area of the wafer functional area of the wafer, and the conductive hole is located at a cutting channel position of the wafer.

4. The wafer-level power module of claim 1, wherein the conductive path comprises at least one conductive hole, and the conductive hole extends from a lower surface of the wafer-level power module to an upper surface.

5. The wafer-level power module of claim 1, wherein the conductive path comprises at least one conductive hole, and the conductive hole is located on a side wall of the wafer-level power module.

6. The wafer-level power module of claim 1, wherein the conductive path comprises at least one connective layer, and the connective layer is used for electrically connecting the wafer functional area of the wafer and the power pin of the passive element in a welding or electroplating mode.

7. The wafer-level power module of claim 1, wherein a first insulating layer is formed on the first surface and the second surface of a substrate of the wafer and an inner wall of a conductive hole, respectively, and a second insulating layer is formed on the surface of the wafer functional area, and the second insulating layer is used for blocking SW power pins.

8. The wafer-level power module of claim 1, wherein the plane size of the wafer-level power module or the plane size of the passive element is the same as the plane size of the wafer.

9. The wafer-level power module of claim 1, wherein the passive element is pre-formed, the passive element comprises a passive element functional area and/or a complete power pin, and the passive element is electrically connected with a chip through welding or electroplating, or is electrically connected with the wafer before cutting; and the passive element is plastic-sealed on the second surface of the wafer to form a support.

10. The wafer-level power module of claim 1, wherein the passive element is grown and formed on the wafer, and is electrically connected with the wafer through sintering or electroplating.

11. The wafer-level power module of claim 1, wherein the passive element comprises a first passive element and a second passive element, and the wafer, the second passive element and the first passive element are sequentially stacked in a vertical direction.

12. The wafer-level power module of claim 11, wherein the plane size of the second passive element is the same as the plane size of the wafer.

13. The wafer-level power module of claim 11, wherein an interconnection is formed between the wafer and the second passive element, and/or, between the second passive element and the first passive element through welding or sintering or electroplating.

14. The wafer-level power module of claim 1, wherein the wafer comprises a first wafer and a second wafer, and the first wafer, the second wafer and the passive element are sequentially stacked in a vertical direction.

15. The wafer-level power module of claim 14, wherein the second wafer comprises at least one conductive path, the conductive path penetrates through a substrate of the second wafer, and the conductive path is located in an interior or a side wall of the second wafer.

16. A wafer-level power module comprises:
a wafer, the wafer comprising a wafer functional area, and the wafer functional area being located on a first surface of the wafer; and
a passive element, the passive element comprising at least one functional conductive layer and a functional dielectric layer, wherein:
the passive element and the wafer are stacked, and an occupied area after stacking is equal to an area of the wafer;
the wafer functional area is electrically connected with the functional conductive layer through a conductive path, at least one part of the conductive path is realized by electroplating a through hole or a semi-through hole, and the conductive path is arranged on a side surface or a middle position of the wafer-level power module;
the wafer is attached to or directly attached to the passive element by means of a filling material, and the passive element provides mechanical strength support for the wafer; and
the functional dielectric layer is disposed between the at least one functional conductive layer of the passive element and the first surface of the wafer.

17. The wafer-level power module of claim 16, wherein the passive element comprises a first passive element and a second passive element, and the first passive element and the second passive element are vertically stacked on a second surface of the wafer respectively.

18. The wafer-level power module of claim 16, wherein the passive element is a multi-phase anti-coupling inductor; wherein the multi-phase anti-coupling inductor comprises at least two magnetic units, and windings of the at least two magnetic units share the same magnetic column, so that the lengths of the windings are equal.

19. The wafer-level power module of claim 18, wherein input pins and output pins of the windings of the multi-phase anti-coupling inductor are arranged in a staggered manner; the windings of each phase of the multi-phase anti-coupling inductor are single-turn or multi-turn, and the windings of each phase are of multi-strand winding structures.

20. The wafer-level power module of claim 16, wherein a power pin comprises an alternating-current voltage pin and a direct-current voltage pin, the alternating-current voltage pin is located in a middle area of the wafer-level power module, and the direct-current voltage pin is located on a periphery of the wafer-level power module.

21. The wafer-level power module of claim 16, wherein the wafer comprises at least one power region, at least one control area and/or a power management area and/or a data processing area, and the planar size of the wafer is the same as the planar size of the passive element.

22. The wafer-level power module of claim 21, wherein the wafer comprises two power regions, and the two power regions are interconnected by means of a rewiring layer, wherein the rewiring layer comprises at least one TSV hole, and the TSV hole is located on a side wall of the wafer.

23. The wafer-level power module of claim 16, wherein an adhesive layer or a metal shielding layer is arranged between the wafer and the passive element.

24. The wafer-level power module of claim 16, wherein the thickness of the wafer is less than 100 μm.

25. The wafer-level power module of claim 16, wherein the wafer-level power module comprises a power pin, the power pin is placed on an outer side surface of the passive element, and the first surface of the wafer is between a second surface of the wafer and the passive element.

26. The wafer-level power module of claim 16, wherein the passive element comprises a capacitor electrically interconnected with a direct-current power pin of the wafer, and/or the passive element comprises a capacitor or a magnetic element electrically interconnected with an alternating-current power pin of the wafer, and/or the passive element comprises a capacitor electrically interconnected with a direct-current pin of a magnetic element.

27. The wafer-level power module of claim 16, further comprising an output capacitor, and wherein the output capacitor integrates pins of the wafer-level power module and is arranged on a lower surface of the wafer-level power module.

28. The wafer-level power module of claim 26, wherein the wafer-level power module further comprises a silicon wafer capacitor array, and the silicon wafer capacitor array comprises an output capacitor and parts of capacitors required by the wafer during operation.

29. A manufacturing method for the wafer-level power module of claim 16, and the manufacturing method comprises the following steps:
a step S1, attaching a plurality of wafers to a jig, thinning the wafers, and tightly combining the wafers with a plurality of passive element layers to form an integrated structure;
a step S2, through a process of laser or etching, opening a through hole or a semi-through hole, electroplating the through hole or the semi-through hole, and electrically connecting the wafer functional area with the functional conductive layer;
a step S4, de-paneled to a plurality of modules through a wafer cutting process, then testing and packaging the modules.

30. The manufacturing method of claim 29, wherein a step S3 is further comprised between the step S2 and the step S4:
the step S3: thinning a second surface of the wafer.

31. The manufacturing method of claim 29, wherein the functional conductive layer of the passive element is formed by combining the wafer and the passive element layer into an integrated structure and then electroplating.

32. A method for manufacturing a wafer-level power module, comprising the following steps:
a step S1: providing a wafer;
a step S2: forming TSV holes in a substrate of the wafer, wherein in the step S2, the TSV holes do not penetrate through the substrate of the wafer;
a step S3: forming a first insulating layer on an inner wall of each TSV hole;
a step S4: filling a metal in each TSV hole, and forming a first metal layer on a first surface of the substrate of the wafer;
a step S5, thinning a second surface of the wafer, exposing the metal in each TSV hole, and leaving a space to a passive element;
a step S6: providing the passive element on the second surface of the wafer;
a step S7, scribing to form an independent power module, wherein the plane size of the power module is the same as the plane size of the wafer.

33. The method of claim 32, wherein the step S6 is:
if the passive element is discrete, molding the passive element to form a plastic package body so as to support the wafer, and in the step S7, performing scribing and cutting from the first surface of the wafer;
if the passive element is a pre-formed splicing plate, the passive element needs to be fixed with the wafer through filling seam; and
positions of the TSV holes are located on cutting channels of a wafer.

34. The method of claim 32, wherein the step S6 comprises:
growing the passive element on the second surface of the wafer.

35. A method for manufacturing a wafer-level power module, comprising the following steps:
a step S1: providing a wafer;
a step S2, forming a first metal layer on a first surface of the wafer, wherein a first surface of the wafer is a functional surface;
a step S3, after the first surface of the wafer is fixed on a carrier, thinning the wafer, and leaving a space to a passive element;
a step S4: forming a TSV hole from a second surface of the wafer to an inside, the TSV hole extending to the first metal layer;
a step S5: forming a first insulating layer on an inner wall of the TSV hole and the second surface of the wafer;
a step S6: filling the TSV hole with a metal, and forming a second metal layer on the second surface of the wafer;
a step S7: providing the passive element on the second surface of the wafer; and
a step S8: scribing to form an independent power module, wherein the plane size of the power module is the same as the plane size of the wafer.

36. The method of claim 35, wherein the step S7 comprises:
if the passive element is discrete, molding the passive element to form a plastic package body so as to support the wafer, and in the step S7, performing scribing and cutting from the first surface of the wafer;
if the passive element is a pre-formed splicing plate, the passive element needs to be fixed with the wafer filling seam;
a position of the TSV hole is located on a cutting channel of a wafer.

37. A method for manufacturing a wafer-level power module, comprising the following steps:
a step S1: providing a wafer;
a step S2: laying a passive element on a second surface of the wafer;
a step S3: forming a conductive hole, the conductive hole penetrating through the wafer and the passive element;
a step S4: forming a first insulating layer in the conductive hole;
a step S5: drilling a deep drilling hole on a surface of the passive element, and forming a conductive hole with a wider width at one end of the conductive hole;
a step S6: forming a metal layer on a first surface of the wafer, the surface of the passive element and the conductive hole;
a step S7: etching for respectively forming required pins on the first surface of the wafer and the surface of the passive element;
a step S8: scribing is carried out at a position of the conductive hole to form an independent power module, and the plane size of the power module is the same as the plane size of the wafer.

38. A method for manufacturing a wafer-level power module, comprising the following steps:
a step S1: providing a wafer;
a step S2, laying a passive element on a second surface of the wafer, wherein an internal metal layer is arranged in the passive element;
a step S3: forming a conductive hole from a first surface of the wafer to an inside, so that the internal metal layer is exposed;
a step S4: forming a first insulating layer in the conductive hole;
a step S5: removing a part of the first insulating layer located outside the internal metal layer, so that a part of the internal metal layer is exposed;
a step S6: filling a metal in the conductive hole, and forming a metal layer on the first surface of the wafer;
a step S7: etching for forming a required pin on the first surface of the wafer;
a step S8: scribing at a position of the conductive hole to form an independent power module, the plane size of the power module being the same as the plane size of the wafer.
